(19) United States
(12) Patent Application Publication
(10) Pub. No.: US 2003/0135795 A1
(43) Pub. Date: Jul. 17, 2003

(54) Integrated circuit and method for operating a test configuration with an integrated circuit

(76) Inventors: Christian Weis, Germering (DE); Pramod Acharya, Munchen (DE); Stefan Dietrich, Turkenfeld (DE); Peter Schrogmeier, Munchen (DE)

Correspondence Address: LERNER AND GREENBERG, P.A., POST OFFICE BOX 2480, HOLLYWOOD, FL, 33022-2480, US

(21) Appl. No.: 10/345,527

(22) Filed: Jan. 16, 2003

(30) Foreign Application Priority Data
Jan. 16, 2002 (DE) 102 01 431.0

(51) Int. Cl. G11B 5/00; G06K 5/04; G11B 20/20; G01R 31/28

(52) U.S. Cl. 714/700

(57) ABSTRACT

An integrated circuit contains a register circuit for storing reference data for a test operation of the integrated circuit and a comparison circuit for comparing data to be read out. The comparison circuit outputs a plurality of comparison signals representing compressed comparison results. A plurality of output circuits are connected to the output of the comparison circuit, the output circuits receive one of the comparison signals in each case. The comparison signals are present at the output circuit over a plurality of clock edges or clock periods of a control clock. Each of the output circuits is connected to an interface pad for externally outputting the comparison signals. In the test operation, an external test device is connected to the interface pads of the integrated circuit. Despite a reduction in the transmission frequency to the test device, the full information content of the comparison signals can be transmitted.

### BACKGROUND OF THE INVENTION

Field of the Invention

The present invention relates to an integrated circuit and a method for operating a test configuration with such an integrated circuit.

As a result of continuous development in the field of integrated circuits, there is a generally steady increase in the operating frequency at which integrated circuits are operated. With the continuous increase in the operating frequencies of integrated circuits, it is increasingly difficult in most cases to test the full functionality of the integrated circuits. At the same time, in order to ensure that test results remain as meaningful as possible, it is important for integrated circuits to be tested at the operating frequency used during normal operation.

However, experience shows that it is comparatively difficult to provide test devices for more recent integrated circuits, which test devices are capable of evaluating with sufficient accuracy the output signals of the integrated circuits when the circuits are tested and operated at their maximum operating frequencies. Frequently, such test devices are not commercially available or are comparatively expensive. Therefore, for reasons of cost, it is often advantageous to implement measures at chip level to make test devices of an older configuration available for more recent chip generations, the test devices only supporting comparatively low frequencies.

### SUMMARY OF THE INVENTION

It is accordingly an object of the invention to provide an integrated circuit and a method for operating a test configuration with an integrated circuit which overcome the above-mentioned disadvantages of the prior art devices and methods of this general type, which, in a test operation, makes output signals available to a test device in a way that utilizes low frequency in comparison with normal operation of the integrated circuit, and nonetheless includes the full information content required to differentiate between a defective integrated circuit and a flawless circuit.

With the foregoing and other objects in view there is provided, in accordance with the invention, an integrated circuit. The circuit contains a terminal for receiving a control clock, a register circuit for storing reference data for a test operation of the integrated circuit, and a comparison circuit connected to the register circuit. The comparison circuit compares-data to be read out with the reference data in the register circuit. The comparison circuit has an output for outputting a plurality of comparison signals representing a compressed comparison result in each case. A plurality of output circuits are connected to the output of the comparison circuit in each case and further connected to the terminal for the control clock. The output circuits receive one of the comparison signals in each case, and the comparison signals are present in each case at a respective one of the output circuits over a plurality of clock edges or clock periods of the control clock. Interface pads are provided, and each of the output circuits are connected to a separate one of the interface pads for externally outputting the comparison signals.

The present invention also addresses the problem of specifying a method for operating a test configuration with such an integrated circuit.

The integrated circuit according to the invention has a register circuit, in which reference data for a test operation of the integrated circuit is stored. A comparison circuit is connected to the register circuit, and is used for comparing data to be read out from the integrated circuit with the reference data from the register circuit. The comparison circuit also has an output for outputting a plurality of comparison signals, which represent a compressed comparison result in each case. Provision is also made for a plurality of output circuits, each of which is connected to the output of the comparison circuit.

In this way, the output circuits receive one of the comparison signals in each case. The comparison signals are present in each case at the respective output circuit over a plurality of clock edges or clock periods of a control clock, which results in a temporal extension of a data eye (reduction of the transmission frequency) by a corresponding factor. Each of the output circuits is connected to a separate interface pad for externally outputting the comparison signals. A plurality of interface pads are therefore used in parallel, in order to transmit the full information content of the comparison signals in spite of the extended data eye. The comparison signals that are output by the comparison circuit are therefore distributed via a plurality of interface pads. The compression ratio of the comparison results is generally selected in such a way that the data eye can be extended such that the test device can still just set an exact so-called strobe during the readout.

In accordance with an added feature of the invention, the comparison circuit is one of a plurality of comparison circuits each having a comparison output. Data words of a first bit width are read out from the memory configuration, the data words being split into a plurality of groups of a second bit width supplied to the plurality of comparison circuits in each case. The comparison circuits are connected to the register circuit storing the reference data of the second bit width. The output circuits are connected in groups to the comparison output of one of the comparison circuits. The comparison output receives a comparison signal in each case, and the comparison signal is different for each of the output circuits. The output circuits output the comparison signal received in each case, several times in succession over the plurality of clock edges or clock periods of the control clock in each case.

In a method for operating a test configuration with the integrated circuit according to the invention, an external test device is connected to the interface pads of the integrated circuit, and reads out the comparison signals that are present at the interface pads.

The invention has the advantage that, in the case of integrated circuits with a comparatively high operating frequency (so-called high-performance modules), whose operating frequency is higher than that of the test device, the invention first and foremost makes it possible to test the integrated circuits at their full frequency range. Test devices with a high operating frequency range are usually very expensive, and are generally subject to long delivery timescales which represent a critical delay factor when marketing a new product. The present invention makes it possible to manage without procuring and commissioning new test devices and thus to save costs, so that new products can to be brought to market sooner in some cases.

The present invention can be applied to various types of integrated circuits, though it is particularly suitable for integrated circuits in the form of memory circuits such as DRAM memory, for example.

In a preferred embodiment of the integrated circuit according to the invention, the output circuits are formed by a parallel-serial converter circuit in each case, which receives an identical comparison signal at each of its parallel inputs, the comparison signals coming from the comparison circuit. The parallel-serial converter circuit outputs the comparison signal at a serial output several times in succession.

In a further embodiment of the integrated circuit according to the invention, the integrated circuit also has a memory configuration with normal memory cells and redundant memory cells for replacing normal memory cells. The redundant memory cells allow the replacement of defective normal memory cells that were identified as faulty during the test operation. In this case, the bit width of the register circuit corresponds to a number of normal memory cells, which are replaced in combination, as an associated cluster, by redundant memory cells. It is therefore possible for one of these numbers of memory cells, the number corresponding to the aforementioned bit width, to generate a combined compressed item of test information, which contains information as to whether one or more of the memory cells are faulty. If there are one or more faulty memory cells in this number of memory cells, all memory cells are replaced as an associated cluster by redundant memory cells.

In a development of the method according to the invention, the test device is operated at a maximum read frequency that it is capable of processing (i.e. the test device can only just set a strobe with temporal accuracy), the read frequency being lower than the operating frequency of the control clock of the integrated circuit. In this case, the number of clock periods or clock edges during which one of the comparison signals is present at the corresponding output circuit is selected in such a way that the number of clock periods or clock edges corresponds to a ratio of the operating frequency of the control clock to the maximum read frequency that can be processed by the test device. For example, if the maximum read frequency that can be processed by the test device is 200 MHz, but the integrated circuit can be operated at an operating frequency of 800 MHz, then a comparison signal will in each case be supplied to the corresponding output circuit over four clock periods (in the case of a SDRAM, for example) or four clock edges (in the case of a DDR SDRAM with twice the data rate, for example). The same comparison signal is therefore output by the output circuit four times in succession, thereby extending a data eye or reducing the transmission frequency by a factor of 4. As a result, the comparatively slow test device can read out perfectly the output signals which are carried by the integrated circuit and which have a relatively higher frequency.

In accordance with an added mode of the invention, there is the step of reading out the comparison signals from the comparison circuit via only one of the output circuits, with one clock edge or clock period in each case, during a further test operation of the integrated circuit.

In accordance with a further mode of the invention, there are the steps of carrying out the test operation using a backend mode during a manufacture of the integrated circuit, and carrying out the further test operation using a front-end mode during the manufacture of the integrated circuit.

In accordance with another mode of the invention, there is the step of using the comparison circuit for setting a compression during the test operation to correspond to a compression set in the further test operation.

Other features which are considered as characteristic for the invention are set forth in the appended claims.

Although the invention is illustrated and described herein as embodied in an integrated circuit and a method for operating a test configuration with an integrated circuit, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of an embodiment of a DRAM memory circuit, which is operated in a test operation in a so-called front-end operating mode according to the invention;

FIG. 2 is a signal diagram showing a data signal and a clock signal of a DDR DRAM;

FIG. 3 is a signal diagram showing data and clock signals of the DDR DRAM in the test operation in the front-end operating mode;

FIG. 4 is a block diagram of an embodiment of the DRAM memory circuit, which is operated in a test operation in a so-called backend operating mode; and

FIG. 5 is a signal diagram for data and clock signals of the DDR DRAM in a test operation in the backend operating mode.

### DESCRIPTION OF THE PREFERRED EMBODIMENTS

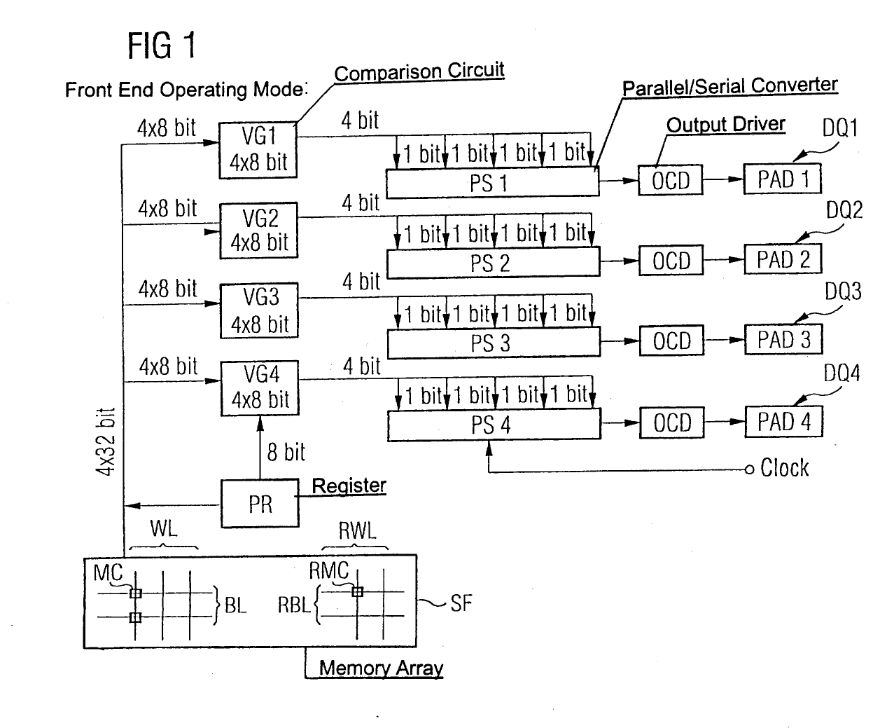

Referring now to the figures of the drawing in detail and first, particularly, to FIG. 1 thereof, there is shown an embodiment of an integrated circuit illustrated in the form of a DRAM which can be operated in a test operation, and which is carried out in a so-called front-end mode during the manufacture of the DRAM. This generally relates to a low-frequency test operation (typically with operating frequencies up to 60 MHz) that is carried out at the wafer level.

FIG. 1 shows a DRAM having a memory cell array SF with normal memory cells MC and redundant memory cells RMC for replacing normal memory cells MC. The memory cells MC and RMC are disposed in each case at intersections of word lines WL and redundant word lines RWL and at intersections of bit lines BL and redundant bit lines RBL respectively. Data is stored in the memory cell array SF. When writing in the test operation mode, 8 bits from a pattern register PR, in which reference data is stored, are multiplied by a factor of four and written to the memory cell array SF as a 32-bit wide data word. The interface pads PAD1 to PAD4 are not involved at this stage. In the read operation, 32-bit wide data words are read out from the memory cell array SF. These are split into 4 groups of 8 bits in each case, and supplied to a respective comparison circuit VG1 to VG4, the comparison circuits being connected to the pattern register PR. The comparison circuits VG1 to VG4 are used for comparing the data words to be read out with the reference data that is stored in the pattern register PR.

There now follows a brief description of a compression method, the use of which in the front-end mode is already known.

In the case of write instructions, the data to be written in the compression operating mode is not injected into the chip via the interface pads and corresponding receiver circuits, but is read out of a register located on the chip and then stored in the memory cell array. This so-called pattern register (of which there may be several, from which one may be selected) is loaded before the write/read accesses. The advantage of using the register PR is that although the chip executes a completely normal write instruction, the data does not have to be supplied externally. Therefore, with write instructions in the compression operating mode, the data pads are not used at all. In the example shown in FIG. 1, a 128M memory has a data-word width of 32, which results in that 32 bit data words are written into the memory. The pattern register PR includes 8 bits in this example and therefore, within a written data word in the compression operating mode, the same bit pattern is written into the four bytes of the data word.

In order to use the smallest possible number of data pads in the case of read instructions, the read data is compressed. This is achieved by comparing the internally read data with the content of the aforementioned pattern register. To this end, the read data is split into groups and compared bit-for-bit with the corresponding bits in the pattern register. In the example of the present 128M memory, 32 read-data bits exist and the pattern register PR is 8 bits wide. In each case, 8 bits of the read data from the memory cell array SF are compared with the 8 bits in the pattern register PR. Such a bit-for-bit comparison results in 8 bits, which are respectively “low” if there were no discrepancies and “high” if there were discrepancies. Since it is insignificant, when evaluating the quality of the memory, whether only one or a plurality of these eight comparison results is “high”, a compression of 8:1 is then carried out. If all eight comparison bits are “low”, the compressed comparison result or compression bit is likewise “low”, and no error occurred in this byte. In this case, the memory chip was able to write and read the byte correctly. As soon as one of the eight comparison bits is “high”, the compressed comparison result likewise becomes “high”, thereby indicating that the memory chip was not able to write and read the whole of the corresponding byte correctly.

Four compressed comparison results per data word are therefore generated in the form of compression bits, the results containing the information for each of the four bytes of a data word, as to whether the byte could be correctly written and read by the memory chip. The four comparison signals in the form of the compression bits are then carried to the exterior of the memory via corresponding interface pads. In this way, the objective of reducing the number of interface pads utilized in the compression operating mode is achieved, from 32 to 4 in this example. Any other compression is theoretically conceivable. In this case, the organization of the memory is established by the choice of compression, in that the bit width of the pattern register PR is selected so that it corresponds exactly to the number of memory cells which have to be replaced together as an associated cluster by corresponding redundant memory cells.

The data words, which are split into 4 groups of 8 bits for each comparison circuit VG1 to VG4, are compared bit-for-bit with the content of the pattern register PR. An output of the comparison circuits VG1 to VG4 is used in each case to output a plurality of comparison signals or compression bits, which represent in each case a compressed comparison result for one respective part of the data word to be read out. If the reference data corresponds to the data that has been read out, then the memory chip has written and read correctly. If at least one reference data bit differs from a data bit which has been read out, then an error occurred during either writing or reading, and the corresponding location in the memory is defective. In such a case, a whole group of 8 bits is replaced by corresponding redundant memory cells.

Each of the four comparison signals that are output by a comparison circuit in the form of four compression bits contains the information about an error that has occurred. The comparison signals must be carried from the memory chip to the exterior and to the test device. To this end, these bits are supplied to an output circuit which is controlled by a clock CLOCK and has the form of a parallel-serial converter PS1, PS2, PS3, PS4 which outputs the comparison signals to corresponding output drivers OCD. These carry the comparison signals towards the interface pads PAD1 to PAD4, to which the test device is attached.

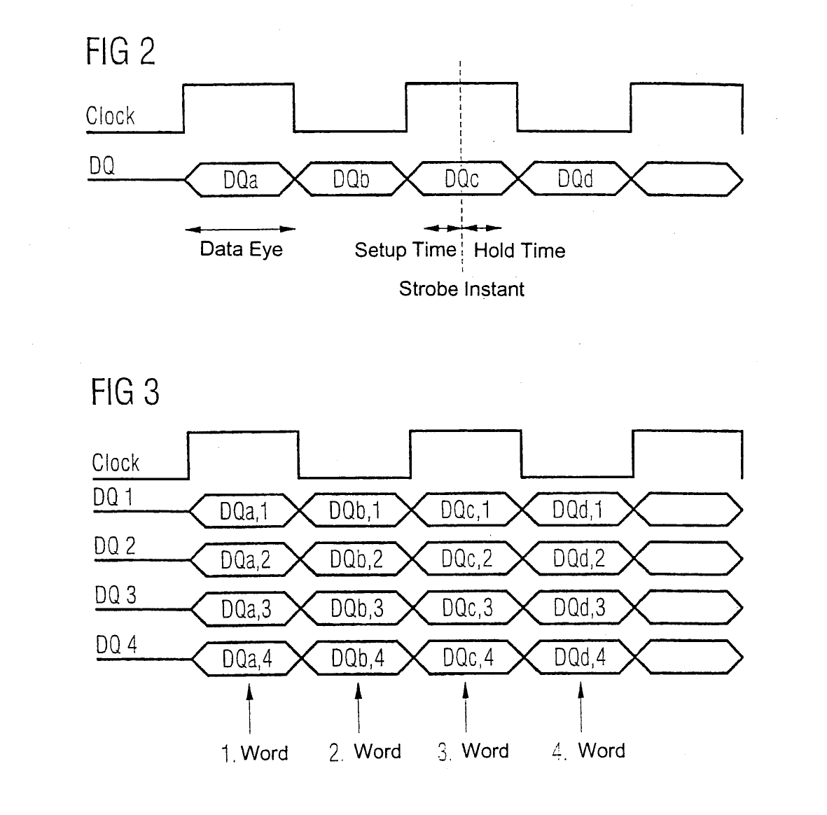

FIG. 2 illustrates a signal diagram for data and a clock signal of a DDR DRAM (Double Data Rate DRAM). In the case of a DDR DRAM, when reading, data is not just output to the exterior of the memory on the rising edge of a clock signal CLOCK, but also on the trailing edge of the clock signal. FIG. 2 shows data DQ and the clock signal CLOCK for a typical DDR protocol. For the sake of simplicity, only the signal CLOCK is illustrated in this case. The corresponding inverted differential clock signal is not shown. Furthermore, only one interface pad is shown with data DQ.

Read data DQa, DQb, DQc and DQd are output at the interface pad. In the case of a normal read operation, such read data is output concurrently on all 32 data interface pads of the 128M memory. At a so-called strobe instant, the test device must evaluate the data carried by the chip. To this end, a certain so-called setup time and hold time must be observed. In the test operation in the front-end operating mode at the wafer level, which test operation typically runs at a maximum of 60 MHz, neither the injection of the clock signal CLOCK nor the evaluation of the data DQ which is carried to the test device represents a significant problem. In the backend operating mode, however, in which the memory chips are to be tested at full operating frequency, up to 500 MHz for example, normal test devices have problems reliably evaluating the read data that is supplied. The core of the problem is the definition of an instant (strobe instant) at which the data is present with sufficient setup time and hold time.

FIG. 3 shows the data signals of four data interface pads, which supply the relevant comparison signals in the form of compression bits to the exterior in the compression operating mode described above. In this case, the four bits, which belong to a data word, are carried concurrently via four interface pads. The compression bits of other data words appear with the following edges of the clock signal CLOCK. With reference to FIG. 1, in the low-frequency front-end operating mode, four data words of 32 bits are each separated into bytes of 8 bits. This results in four groups of 4 bytes each. The first byte of each data word (4 bytes in total) is then transmitted to the first comparison circuit VG1 with four 8-bit comparisons in each case, resulting in the compression bits DQa,1, DQb,1, DQc,1 and DQd,1 as illustrated in FIG. 3. These and the remaining compression bits are subsequently carried to the parallel-serial converters PS1 to PS4, and carried from there with rising and trailing clock edges of the clock signal CLOCK to the driver OCD, and carried from there to the relevant interface pad PAD1 to PAD4. The parallel-serial converter circuits PS1 to PS4 receive 4 bits simultaneously in each case, and output these consecutively with rising and trailing edges in accordance with the DDR protocol.

In the backend operating mode, the following problem arises for so-called high-performance DDR DRAMs which work with a very high clock speed (higher than 300 MHz). Unlike the wafer test in the front-end operating mode, the module test in the backend operating mode is not carried out with a reduced clock speed. Therefore, as a result of the DDR protocol, at a clock speed of 400 MHz, for example, the test device has to evaluate data that is carried by the chip at a frequency of 800 MHz. At this frequency, conventional test devices are no longer able to set strobes with sufficient accuracy. It is therefore necessary to purchase expensive, special test devices or to carry out a module test at reduced speed, which can lead to quality problems.

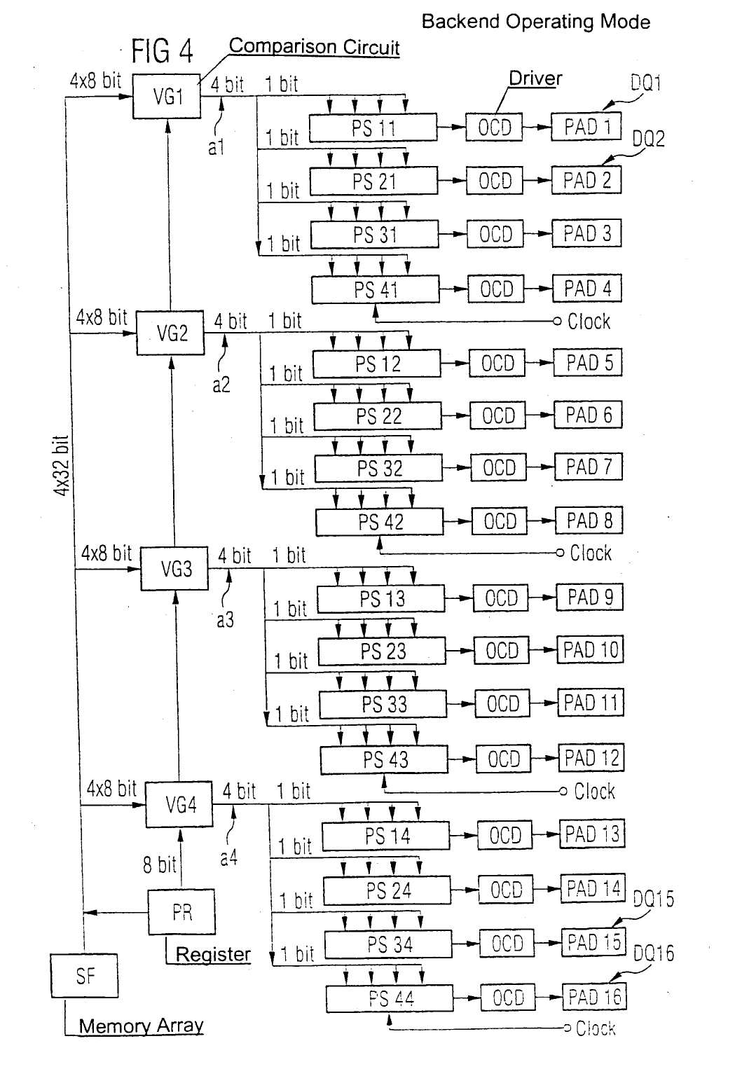

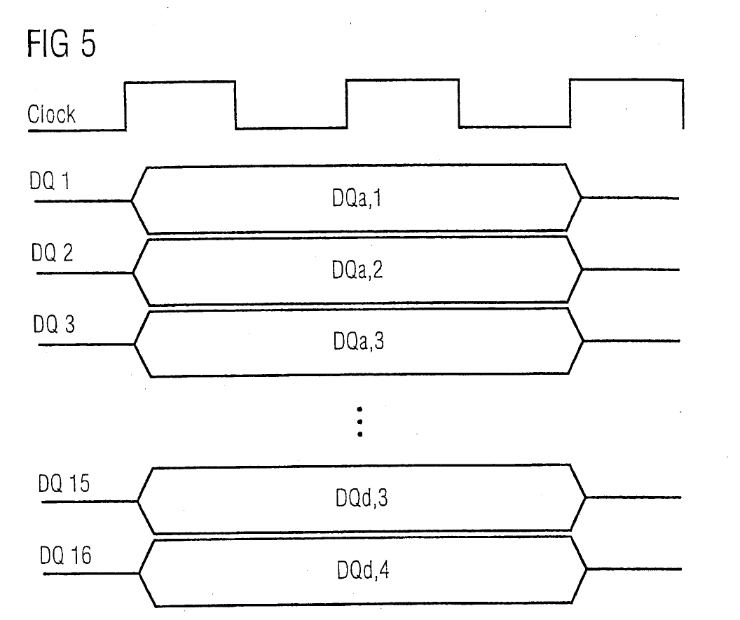

FIG. 4 shows an embodiment of a DRAM that can be operated in a test operation in the backend operating mode in such a way that the aforementioned problem does not occur. As per the memory according to FIG. 1, the comparison circuits VG1 to VG4 are provided in each case, and connected to the pattern register PR. The comparison circuits VG1 to VG4 are used for comparing data words to be read out with the reference data in the pattern register PR. As per the memory shown in FIG. 1, a plurality of comparison signals are output in the form of compression bits at outputs a1 to a4 of the comparison circuits VG1 to VG4 in each case, the signals representing a compressed comparison result for one part respectively of the data word to be read out.

Unlike the memory shown in FIG. 1, the memory shown in FIG. 4 is equipped with a plurality of output circuits in the form of parallel-serial converter circuits PS11 to PS44, which are connected in groups in each case to an output of one of the comparison circuits VG1 to VG4. For example, the parallel-serial converters PS11, PS21, PS31, PS41 are connected in each case to the output al of the comparison circuit VG1. They each receive one compression bit, the bits being different for each parallel-serial converter. Each of the parallel-serial converters PS11 to PS44 is connected to a separate interface pad PAD1 to PAD16 for external output of the compression bits. Each of the compression bits of a comparison circuit is present at a separate assigned parallel-serial converter circuit. The parallel-serial converters receive an identical compression bit at each of their parallel inputs, and output this bit at the serial output several times in succession at a rising or trailing edge of the clock signal in each case.

The memory circuit shown in FIG. 4 extends a data eye of the compression bits to be output, since it uses more than the four data interface pads shown in FIG. 1. In the present example shown in FIG. 4, the data eye is increased by a factor of four, and 16 data interface pads are used to output the relevant compression bits instead of 4 data interface pads. The 16 parallel-serial converters now involved no longer receive four different compression bits as per the comparable parallel-serial converters shown in FIG. 1, but receive the same compression bit four times. They therefore output the same data four times in succession, thereby extending the data eye by a factor of 4. This is enough for the connected test device to set the strobe with sufficient accuracy.

The use of a plurality of data interface pads in a test operation in the backend operating mode does not generally present any difficulties, since all the so-called balls or pins of the modules are normally bonded in the backend operating mode. Therefore the data eye can be extended here, since the compression mode is used as in the case of a test operation in the front-end operating mode and, by contrast, more data interface pads can be used for data output. In order to achieve this, the configuration of a memory as shown in FIG. 1 is changed to give a memory as shown in FIG. 4. The compression in the test operation in the backend mode corresponds to the compression in the test operation in the front-end mode.

FIG. 5 shows a signal diagram for the data DQ1 to DQ16 at the interface pads PAD1 to PAD16 of the memory shown in FIG. 4, which data is output in the form of the compression bits DQa,1 to DQd,4 in a test operation in the backend operating mode. In this case, the signal diagram according to FIG. 5 is analogous to the signal diagram according to FIG. 3, which shows a data output for a front-end operating mode. It is evident from the signal diagram in FIG. 5 that the data eye is increased by a factor of 4 in comparison with the data eye shown in FIG. 3.

For reasons of simplicity, the invention was explained with reference to a DDR DRAM with a so-called prefetch of 4 and a pattern register with a bit width of 8 bits. “Prefetch” means that a plurality of data words is concurrently read out from the memory cell array in each case. With a prefetch of 4, which was implemented in the case of the present 128M DRAM, 4 data words of 32 bits are read out from the memory cell array at the same time. In the compression operating mode, which likewise works with a prefetch of 4, 4 data words of 32 bits are therefore likewise read-out from the memory concurrently, split into 16 groups of 8 bits concurrently, and 16 comparison signals are generated concurrently in the form of compression bits, which contain the information for a total of 16 bytes of 4 data words, as to whether an error occurred when writing or reading.

However, the proposed concept according to the invention can readily be extended to all memory circuits. The compression ratio simply has to be selected in such a way that the data eye can be extended such that the test device to be connected can set an accurate strobe. Using the principle according to the invention, other types of integrated circuits, which generally carry information to the exterior at a specific data rate, can also be tested by test devices with a lower frequency design.

We claim:

1. An integrated circuit, comprising:
a terminal for receiving a control clock;
a register circuit for storing reference data for a test operation of the integrated circuit;
a comparison circuit connected to said register circuit, said comparison circuit comparing data to be read out with the reference data in said register circuit, said comparison circuit having an output for outputting a plurality of comparison signals representing a compressed comparison result in each case;
a plurality of output circuits connected to said output of said comparison circuit in each case and further connected to said terminal for the control clock, said output circuits receiving one of the comparison signals in each case, and the comparison signals being present in each case at a respective one of said output circuits over a plurality of clock edges or clock periods of the control clock; and
interface pads, each of said output circuits connected to a separate one of said interface pads for externally outputting the comparison signals.

2. The integrated circuit according to claim 1, wherein said output circuits are each formed of a parallel-serial converter circuit, said parallel-serial converter circuit has parallel inputs receiving an identical comparison signal, the comparison signals coming from said comparison circuit, and said parallel-serial converter circuit has a serial output outputting a comparison signal at several times in succession.

3. The integrated circuit according to claim 1, wherein each of the comparison signals from said comparison circuit is present at a separate assigned one of said output circuits.

4. The integrated circuit according to claim 1, further comprising a memory configuration having memory cells and redundant memory cells for replacing said memory cells, and said register circuit having a bit width corresponding to a number of said memory cells replaced in combination as an associated cluster by said redundant memory cells.

5. The integrated circuit according to claim 4, wherein:
said comparison circuit is one of a plurality of comparison circuits each having a comparison output;
data words of a first bit width are read out from said memory configuration, the data words being split into a plurality of groups of a second bit width supplied to said plurality of comparison circuits in each case, said comparison circuits connected to said register circuit storing the reference data of the second bit width; and
said output circuits connected in groups to said comparison output of one of said comparison circuits, said comparison output receiving a comparison signal in each case, the comparison signal is different for each of said output circuits, said output circuits output the comparison signal received in each case, several times in succession over the plurality of clock edges or clock periods of the control clock in each case.

6. A method for operating a test configuration having an integrated circuit according to claim 1, which comprises the steps of:
connecting an external test device to the interface pads; and
reading out the comparison signals during a test operation.

7. The method according to claim 6, further comprising the steps of:
operating the external test device at a maximum read frequency that the external test device is capable of processing, the maximum read frequency being lower than an operating frequency of the control clock; and
selecting a number of one of clock periods and clock edges, during which one of the comparison signals is present at a corresponding one of the output circuits, such that the number corresponds to a ratio of the operating frequency of the control clock to the maximum read frequency that can be processed by the external test device.

8. The method according to claim 6, further comprising the step of:
reading out the comparison signals from the comparison circuit via only one of the output circuits, with one clock edge or clock period in each case, during a further test operation of the integrated circuit.

9. The method according to claim 8, which comprises:
carrying out the test operation using a backend mode during a manufacture of the integrated circuit; and
carrying out the further test operation using a front-end mode during the manufacture of the integrated circuit.

10. The method according to claim 8, which comprises using the comparison circuit for setting a compression during the test operation to correspond to a compression set in the further test operation.
